(19) United States
(12) Patent Application Publication
(10) Pub. No.: US 2019/0267571 A1
(43) Pub. Date: Aug. 29, 2019

(54) PACKAGE STRUCTURE

(71) Applicant: STARDUST OPTRONICS CORPORATION, HSINCHU CITY (TW)

(72) Inventors: MENG-HUNG HSIN, NEW TAIPEI CITY (TW); YU-HUNG CHEN, TAOYUAN CITY (TW); CHIN-CHIH LIN, KAOHSIUNG CITY (TW)

(21) Appl. No.: 16/285,021

(22) Filed: Feb. 25, 2019

(30) Foreign Application Priority Data
Feb. 28, 2018 (CN) 201810168223.7

(51) Int. Cl. H01L 51/52; H01L 51/56

(52) U.S. Cl. CPC H01L 51/5253; B82Y 30/00; H01L 51/56; H01L 51/5246

(57) ABSTRACT

The present invention provides a package structure. The package structure includes a substrate, an electronic component layer, an organic polymer layer and a protective layer. The electronic component layer is disposed on the substrate, the organic polymer layer is disposed on the electronic component layer, and the protective layer is disposed on the organic polymer layer. Therefore, compared with the conventional package structure, the present invention omits the fabrication of at least one passivation layer having an inorganic material, and at the same time simplifies the fabrication process and the layers of the package structure, thereby reducing the cost and increasing the productivity.

### BACKGROUND

The present invention is related to a package structure; in particular, to a package structure in which an organic polymer layer is disposed directly on an electronic component layer.

With the advancement and progression of electronic products, electronic products have become indispensable to modern life. During the manufacturing process of the electronic products, a packaging process is often carried out to form a package structure that protects the electronic components within the electronic products, so as to, for example, preventing moisture, oxygen or physical damages. In order to obtain a package structure with a satisfactory protection level and reduce the manufacturing cost of the package structure at the same time, the industry has devoted to the improvement to the manufacturing process, material and structure of the package structure, so as to increase the reliability of the electronic product and reduce the manufacturing cost thereof.

### BRIEF SUMMARY OF THE INVENTION

The present invention provides a package structure, wherein an organic polymer layer thereof is disposed directly on an electronic component layer, which reduces the manufacturing cost and complexity of the package structure, thereby reducing the cost and increasing the productivity.

Embodiments of the present invention provide a package structure including a substrate, an electronic component layer, an organic polymer layer, and a protective layer. The electronic component layer is disposed on the substrate, and the organic polymer layer is directly disposed on the electronic component layer, and the protective layer is disposed on the organic polymer layer.

Since the organic polymer layer in the package structure of the present invention is disposed directly on the electronic component layer, and the organic polymer layer does not undergo a chemical reaction with the electronic component layer which may otherwise deteriorate the organic polymer layer or the electronic component layer, while at the same time maintain the protective effect of the organic polymer layer; therefore, as compared with conventional package structures, the present invention omits the fabrication of at least one passivation layer having an inorganic material, and at the same time simplifies the fabrication process and the layers of the package structure, thereby reducing the cost and increasing the productivity, as well as reducing the thickness of the package structure.

### BRIEF DESCRIPTION OF THE DRAWINGS

FIG. 1 is a schematic sectional view of the package structure according to the first embodiment of the present invention.

FIG. 2 is a partial schematic top view of the package structure according to the first embodiment of the present invention.

FIG. 3 is a schematic sectional view of the electronic component layer according to one embodiment of the present invention.

FIG. 4 is a schematic sectional view of the package structure according to the second embodiment of the present invention.

FIG. 5 is a partial schematic top view of the package structure of the second embodiment of the present invention.

FIG. 6 is a schematic sectional view of the package structure according to the third embodiment of the present invention.

FIG. 7 is a schematic sectional view of the package structure according to the fourth embodiment of the present invention.

FIG. 8 is a schematic sectional view of the package structure according to the fifth embodiment of the present invention.

### DETAILED DESCRIPTION

Embodiments of the present invention are provided below, and the contents of the present invention and the effects to be achieved are described in connection with the accompanying drawings so that persons having ordinary skill in the art may further understand the present invention. It should be noted that the accompany drawings are simplified schematic drawings, and accordingly, only components and structural relationships relevant to the present invention are shown so as to provide a clear description to the basic framework or embodiments of the present invention, whereas the actual components and layouts may be more complex. Further, to facilitate the description, the components shown in the accompanying drawings of the present invention are not drawn to reflect their actual numbers, shapes, or sizes, and the specific ratio of said components may be adjusted depending on the design needs.

Throughout the present disclosure, the terms “comprising,” “including” and/or “having,” when used in connection with the existence of said features, areas, steps, operations, and/or components, do not exclude the exist4ence or addition of one or more other. When a component such as a layer or area is referred to as being disposed “on” another component (or a variant thereof) or extended “onto” another component, it may be disposed on or extended onto said another component directly, or there may be an intervening component between the two. On the other hand, when a component is referred to as being disposed “directly” on another component (or a variant thereof) or extended “directly” onto another component, there is no intervening component between the two. Also, when a component is referred to as being “electrically connected” with another component (or a variant thereof), it may be connected with another component directly or connected with another component indirectly via one or more components.

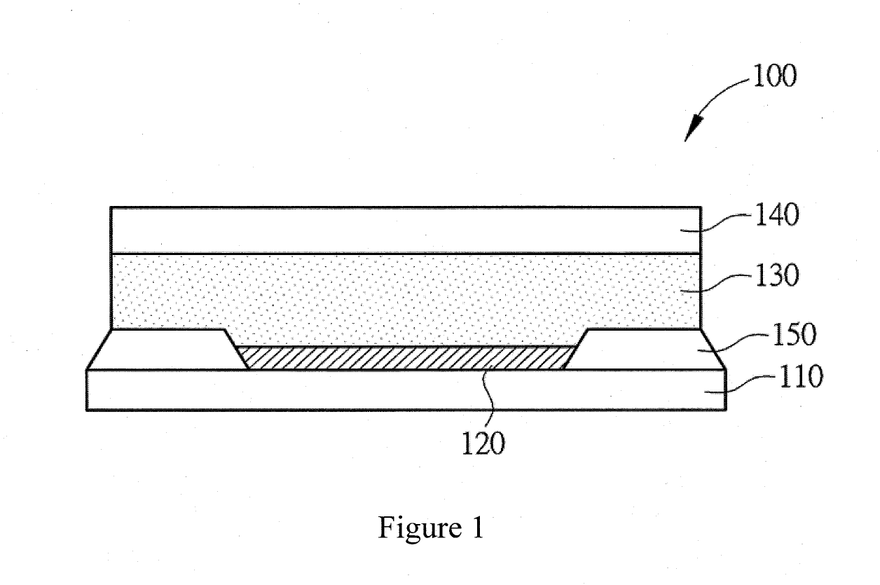

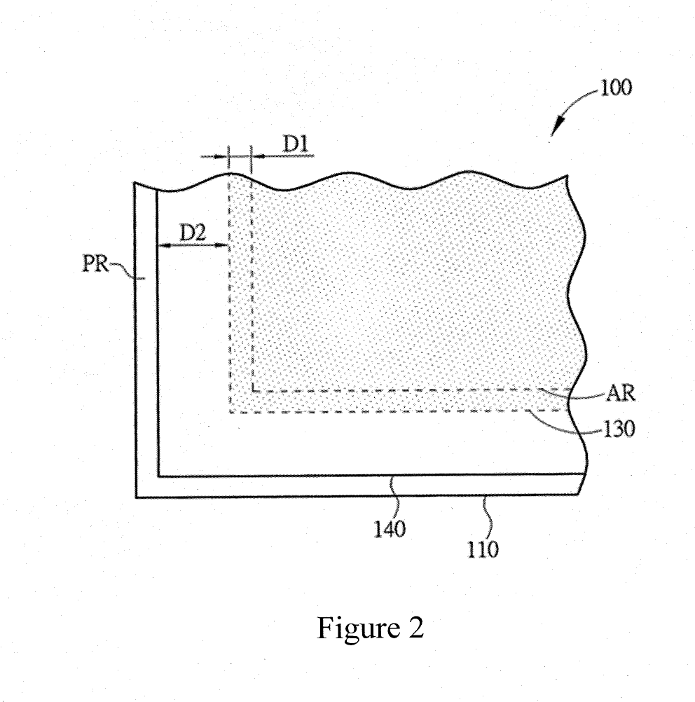

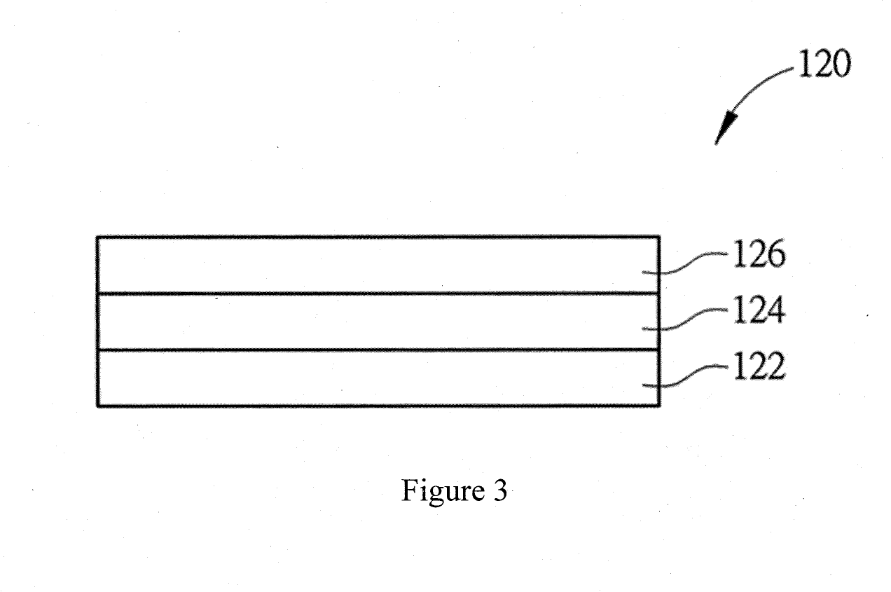

Please refer to FIG. 1 to FIG. 3; FIG. 1 is a schematic sectional view of the package structure according to the first embodiment of the present invention; FIG. 2 is a partial schematic top view of the package structure according to the first embodiment of the present invention; FIG. 3 is a schematic sectional view of the electronic component layer according to one embodiment of the present invention; wherein the position shown in FIG. 2 is a corner of the package structure 100 of the first embodiment. The present package structure 100 is a package structure of, for example, an organic light-emitting diode (OLED) display; however, the present invention is not limited thereto; rather, the package structure 100 may be a package structure of other types of displays, a package structure of an electronic component, e.g., a capacitor, or a package structure of other suitable electronic components, e.g., a microelectromechanical system (MEMS). As shown in FIG. 1 and FIG. 2, the package structure 100 according to the present embodiment comprises a substrate 110, an electronic component layer 120, an organic polymer layer 130 and protective layer 140, and has an active area AR and a peripheral area PR disposed at the periphery of the active area AR, wherein the active area AR is configured to display the image, and the peripheral area PR is configured to accommodate a portion of the circuits. The substrate 110 is configured to bear electronic components, structures or films, and the substrate 110 of the present embodiment may be a hard substrate, such as a glass substrate, plastic substrate, quartz substrate or sapphire substrate; or a flexible substrate comprising such as polyimide (PI) materials or polyethylene terephthalate (PET) materials; however, the present invention is not limited thereto.

The electronic component layer 120 is disposed on the substrate 110, and comprises at least one electronic component for providing specific functions, wherein the electronic component may be at least one of an active device and a passive device, and since the package structure 100 of the present embodiment is the package structure of the OLED display, the electronic component layer 120 in the active area AR may comprise the organic light-emitting diode structure and other necessary electronic components (e.g., conductive wires), so as to provide the light-emitting and image displaying functions; however, the present invention is not limited thereto. In another embodiment, when the package structure 100 is a capacitor package structure, then the electronic component layer 120 may comprise a capacitor. Since the electronic component layer 120 of the present embodiment comprises an organic light-emitting diode structure; accordingly, as shown in FIG. 3, the electronic component layer 120 of the present embodiment may have two conductive electrodes 122, 126 disposed therewithin and an active layer 124 disposed between the two conductive electrodes 122, 126, wherein the active layer 124 may, for example, convert the electricity into solar energy by means of charge combination or charge separation; however, the membrane of the electronic component layer 120 is not limited thereto; for example, the electronic component layer 120 may further comprise an insulation layer configured to separate the conductive wires; and the insulation layer includes, for example, a silicon oxide or silicon nitride layer. Moreover, the package structure 100 of the present embodiment may further comprise, optionally, a pixel defining layer 150 (PDL), which is configured to define the active area AR and separate each pixels; that is, separate the electronic component layer 120 within the active area AR; however, the present invention is not limited thereto.

The organic polymer layer 130 is directly disposed on the electronic component layer 120; that is, the organic polymer layer 130 is in direct contact with the electronic component layer 120, so as to protect the electronic component layer 120. In the present embodiment, the organic polymer layer 130 is fabricated by firstly coating or printing the oligomers directly on the electronic component layer 120, followed by irradiating the oligomers with an energy source so that the oligomers are polymerized to form the organic polymer layer 130, wherein the energy source may be, for example, heat energy or radiation energy, which means that the oligomers may be polymerized with heating or light-irradiation; for example, the oligomers may be heated to about 60° C. to about 120° C. for polymerization, or the oligomers may be irradiated with the light having a wavelength of about 300 nanometers (nm) to about 500 nm for polymerization, whereas the power applied to the oligomers may be about 0.1 to 100 mW/cm², but the fabrication of the organic polymer layer 130 is not limited thereto. It should be noted that, since the organic polymer layer 130 of the present embodiment should be disposed on the electronic component layer 120 directly, the organic polymer layer 130 may comprise a material that is not susceptible to the chemical reaction and deterioration upon contact with the and electronic component layer 120, so as to preserve the protection efficacy of the organic polymer layer 130; further, by using the fabrication method as described above, it is feasible to obtain an organic polymer layer 130 that comprises a material polymerizable to form at least two polymers of the polymethyl methacrylate (PMMA)-based polymers, such as, acrylate or derivatives thereof, methyl acrylate or derivatives thereof, or methyl methacrylate or derivatives thereof; however, the present invention is not limited thereto; in some cases, the polymers may have a fluorine content of about 5%-55%, a molecular weight of 1000˜01000000, and is water-repellent. Moreover, with respect to the disposition of the organic polymer layer 130, for example, in the top view direction of the substrate 110, the size of the organic polymer layer 130 illustrated in FIG. 2 may be greater than the size of the active area AR; that is, the organic polymer layer 130 at least covers and protects the electronic component layer 120 in the active area AR, so as to provide a better protection to the electronic component layer 120, whereas in the present embodiment, the periphery of the organic polymer layer 130 and the periphery of the active area AR may have a distance D1 of no less than 1 micrometer (μm); however, the present invention is not limited thereto.

The protective layer 140 may be, for example, adhered onto the organic polymer layer 130, and is configured to protect the overall package structure 100 and exhibits the barrier functionality and improving the weather resistance. With respect to the disposition of the protective layer 140, for example, in FIG. 2, in the top view direction of the substrate 110, the size of the substrate 110 may be greater than the size of the protective layer 140, and the size of the protective layer 140 may be greater than the size of the organic polymer layer 130, in the present embodiment, the periphery of the protective layer 140 and the periphery of the organic polymer layer 130 may have a distance D2 of no less than 1 micrometer and no greater than 350 micrometers, or no less than 1 micrometer and no greater than 700 micrometers; however, the present invention is not limited thereto.

In the conventional package structure, when the conventional film containing organic materials is in contact with the electronic component layer 120, after the energy irradiation of the manufacturing process, the energy initiator in the organic material-containing film releases free radicals or similar ionized molecules that undergo a chemical reaction with the materials in the electronic component layer, thereby jeopardizing the features or use life of the electronic component layer 120 and affecting the protection efficacy of the conventional organic materials; hence, after the completion of the fabrication of the electronic component layer 120, a passivation layer (e.g., a silicon oxide layer or a silicon nitride layer) having inorganic materials is generally formed on the electronic component layer 120, and then an organic material-containing film is formed on the passivation layer so as to protect the electronic component layer 120; that is, an inorganic passivation layer is required between the conventional organic film and the electronic component layer 120 so as to separate the electronic component layer 120 and the organic material. However, since the inorganic passivation layer has to be fabricated with deposition processes such as the plasma-enhanced chemical vapor deposition (PECVD) or atomic layer deposition (ALD), also the costs for those manufacturing process are usually higher, and the apparatuses required for carrying out such processes are more expensive, resulting that the overall cost for the package structure is increased. On the other hand, due to the organic polymer layer 130 of the present embodiment includes the above-mentioned materials, the organic polymer layer 130 can be disposed on electronic component layer 120 directly, thereby eliminate the need for the fabrication of the inorganic passivation layer, and simplifies the fabrication process of the film layers of the package structure 100 at the same time, thereby reduces the cost and improves the productivity, and even reduces the thickness of the package structure 100. Additionally, in the present embodiment, in order to further improve the protection level of the organic polymer layer 130, the organic polymer layer 130 may include a material capable of isolate the moisture and oxygen so as to prevent the permeate of the moisture and oxygen that may damage the electronic components of the electronic component layer 120; however, the present invention is not limited thereto. Moreover, the thickness of the organic polymer layer 130 of the present embodiment may range from 0.1 micrometer to about 10 micrometers, so as to encapsulate the particles that may adhere to the electronic component layer 120 during the fabrication process so as to prevent the discharging caused by the protrusion of particles; however, the present invention is not limited thereto.

Additionally, the package structure 100 of the present embodiment may further comprise other optional films/layers depending on the need, for example, the package structure 100 may further comprise a color filter (CF) layer or a black matrix (BM) layer, disposed on the organic polymer layer 130, to improve the display quality.

The package structure of the present invention is not limited to the above-mentioned embodiments, other embodiments are described below; however, to simplify the discussion and highlight the differences between these and the above-mentioned embodiments, in the following descriptions, the same or similar components are designated with the same or similar numeral numbers and the repetitive portions are omitted for the sake of brevity.

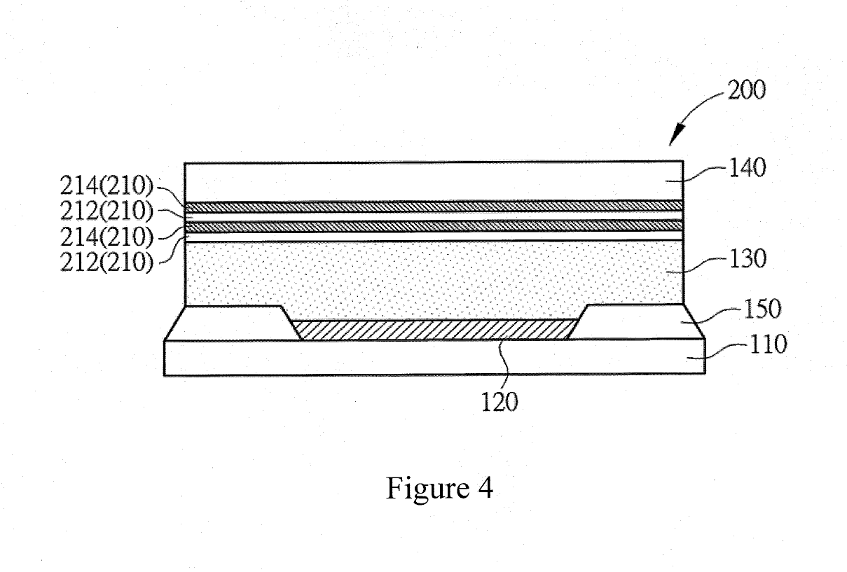

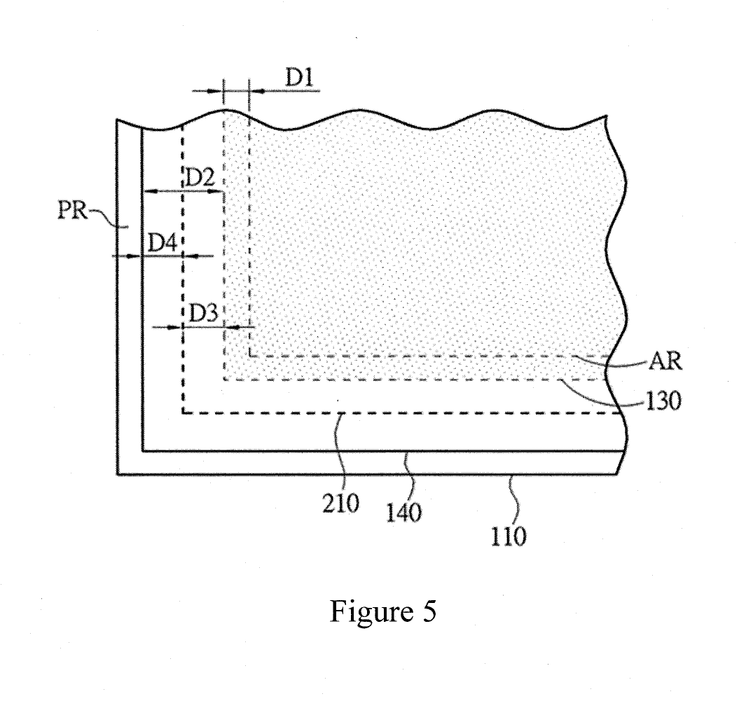

Please refer to FIG. 4 and FIG. 5; FIG. 4 is a schematic sectional view of the package structure according to the second embodiment of the present invention; FIG. 5 is a partial schematic top view of the package structure of the second embodiment of the present invention, wherein the position shown in FIG. 5 is a corner of the package structure 200 of the second embodiment. As shown in FIG. 4 and FIG. 5, the difference between the present embodiment and the first embodiment is that the package structure 200 of the present embodiment may further include at least one inorganic insulating layer 210, disposed between the organic polymer layer 130 and the protective layer 140, wherein the material of the inorganic insulating layer 210 may comprise, for example, silicon oxide, silicon oxynitride, silicon nitride and at least one other materials suitable for use in the inorganic insulating materials of the OLED, so as to improve the protection level, such as water-resistance. Specifically, in FIG. 4, the package structure 200 comprises two first inorganic insulating layers 212 and two second inorganic insulating layers 214, wherein the materials or ratio of materials comprised in the first inorganic insulating layer 212 differ from that of the second inorganic insulating layer 214; for example, the first inorganic insulating layer 212 comprises at least one of the silicon oxide, silicon oxynitride and silicon nitride, whereas the second inorganic insulating layer 214 comprises another of the silicon oxide, silicon oxynitride and silicon nitride, and the first inorganic insulating layer 212 and the second inorganic insulating layer 214 are stacked alternately; in other words, inorganic insulating layers 210 of different materials or different material ratios are stacked alternately; however, the present invention is not limited thereto. In the present embodiment, the number of the first inorganic insulating layer 212 is the same as the number of the second inorganic insulating layer 214; however, the present invention is not limited thereto; in another embodiment, the number of the first inorganic insulating layer 212 differs from the number of the second inorganic insulating layer 214; for example, the difference between the number of the first inorganic insulating layer 212 and the number of the second inorganic insulating layer 214 is 1. In another embodiment, one or a plurality of inorganic insulating layers 210 may be disposed directly between the organic polymer layer 130 and the protective layer 140, wherein the materials or material ratios of a portion of the plurality of inorganic insulating layers 210 may be the same or the materials or material ratios of each of the plurality of inorganic insulating layers 210 may be different. Each inorganic insulating layer 210 may be fabricated with the CVD process or ALD process, but the fabrication process is not limited thereto. Also, with respect to the disposition of the inorganic insulating layer 210, for example, in FIG. 5, in the top view direction of the substrate 110, the size of the substrate 110 may be greater than the size of the protective layer 140, and the size of the inorganic insulating layer 210 may be greater than the size of the organic polymer layer 130 and smaller than the size of the protective layer 140, so as to prolong and improve the protection level; in the present embodiment, the periphery of the inorganic insulating layer 210 and the periphery of the organic polymer layer 130 may have a distance D3 of no less than 1 micrometer and no greater than 350 micrometers, whereas the periphery of the inorganic insulating layer 210 and the periphery of the protective layer 140 have a distance D4 of no less than 1 micrometer and no greater than 350 micrometers; however, the present invention is not limited thereto. Moreover, the thickness of each inorganic insulating layer 210 (that is, each of the first inorganic insulating layers 212 and each of the second inorganic insulating layers 214) may range from about 0.5 nm to about 500 nm, so that it is suitable for thin film encapsulation (TFE); however, the present invention is not limited thereto.

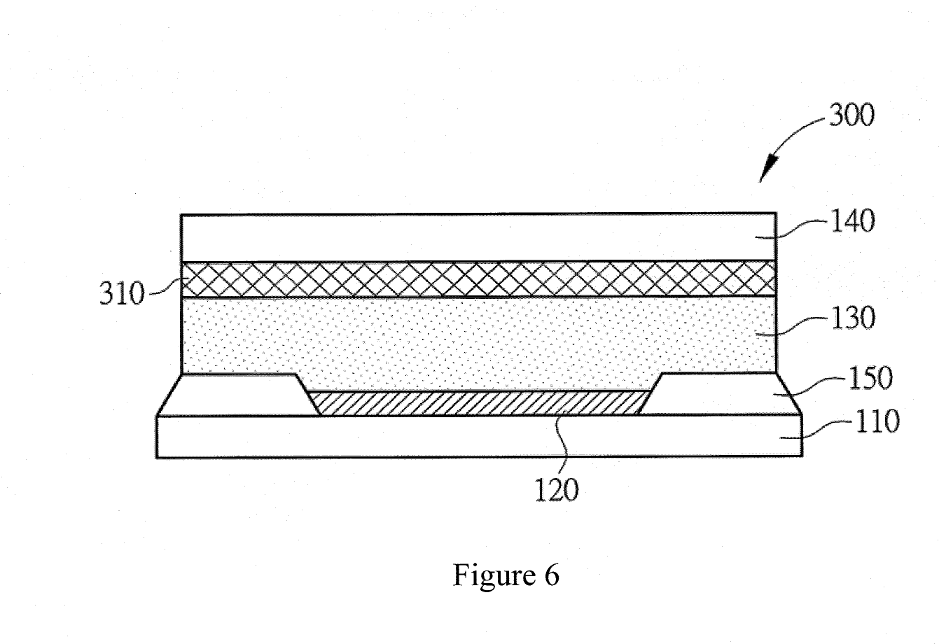

Please refer to FIG. 6, FIG. 6 is a schematic sectional view of the package structure according to the third embodiment of the present invention. As shown in FIG. 6, the difference between the present embodiment and the first embodiment is that the package structure 300 of the present embodiment may further comprise an adhesive layer 310, disposed between the organic polymer layer 130 and the protective layer 140, to improve the adhesion between the organic polymer layer 130 and the protective layer 140. The adhesive layer 310 of the present embodiment is adhesive on both sides, and after being adhered onto the surface of the organic polymer layer 130, the protective layer 140 is then disposed on the adhesive layer 310, so that the protective layer 140 may be adhered more securely on the surface of the package structure 300 via the adhesive layer 310. On the other hand, the adhesive layer 310 may have sealing and water- and oxygen-insulating functions; however, the present invention is not limited thereto.

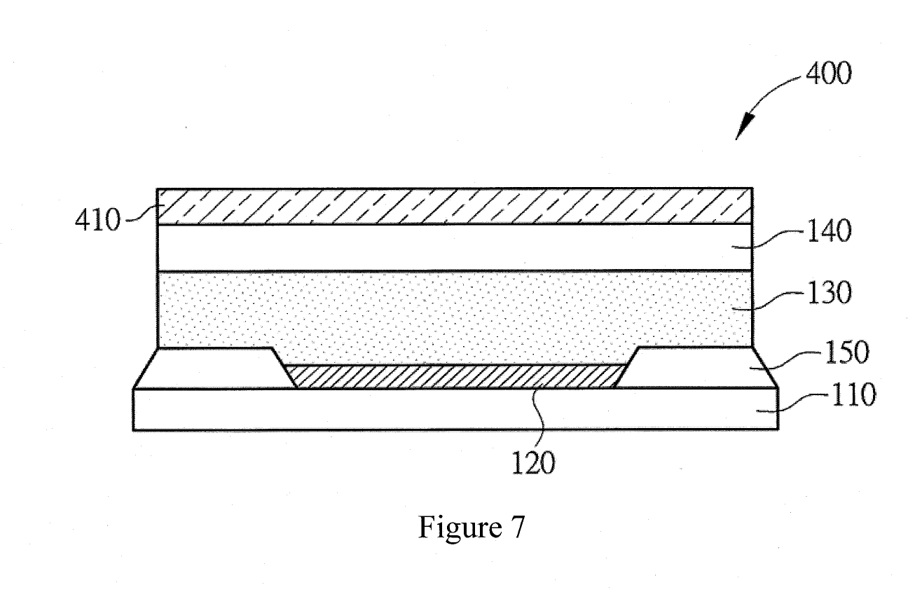

Please refer to FIG. 7, FIG. 7 is a schematic sectional view of the package structure according to the fourth embodiment of the present invention. As shown in FIG. 7, the difference between the present embodiment and the first embodiment is that the package structure 400 of the present embodiment may further comprise an optical film 410 disposed on protective layer 140, so as to improve the imaging quality and effect. In the present embodiment, the optical film 410 may be disposed on the protective layer 140 by means of, for example, adhesion with an adhesive, so that the optical film 410 has the optical functions, for example, it may be a polarizing plate or an anti-reflection film; however, the present invention is not limited thereto.

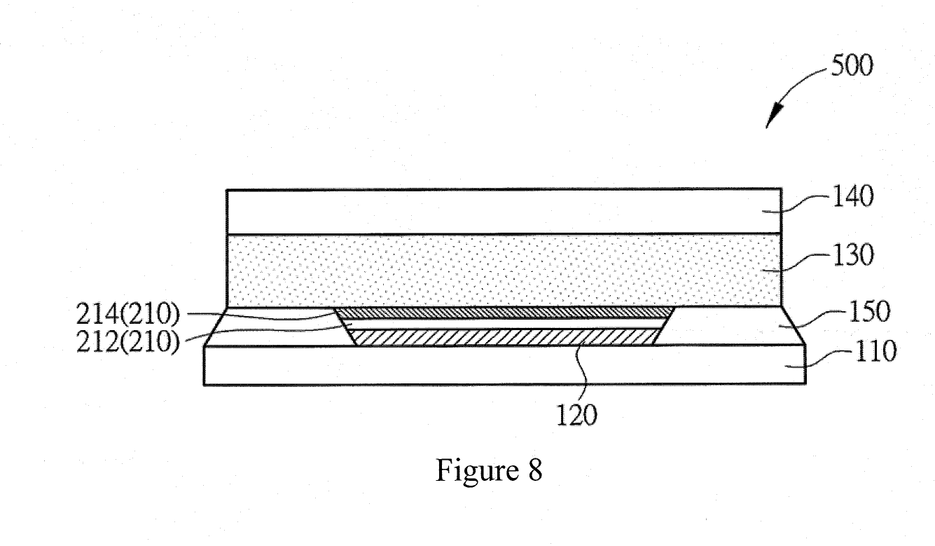

Please refer to FIG. 8, FIG. 8 is a schematic sectional view of the package structure according to the fifth embodiment of the present invention. As shown in FIG. 8, the difference between the present embodiment and the first embodiment is that at least one inorganic insulating layer 210 of the package structure 500 of the present embodiment is disposed between the organic polymer layer 130 and the electronic component layer 120; that is, the organic polymer layer 130 of the present embodiment is not directly disposed on the electronic component layer 120, such that the organic polymer layer 130 and the electronic component layer 120 is not in direct contact. In FIG. 8, two illustrative inorganic insulating layers 210 (one first inorganic insulating layer 212 and one second inorganic insulating layer 214) are shown, and they are disposed between two pixel defining layers 150, yet the number and arrangement of the inorganic insulating layer 210 is not limited thereto. Moreover, an inorganic insulating layer 210 may be optionally disposed between the organic polymer layer 130 and the protective layer 140. The arrangement and material of the inorganic insulating layer 210 are similar to those described in connection with the second embodiment, and hence, detailed descriptions are omitt4ed herein for the sake of brevity.

In view of the foregoing, since the organic polymer layer of the package structure according to the present invention may be directly disposed on the electronic component layer, and the organic polymer layer of the present invention does not undergo a chemical reaction with the electronic component layer that may otherwise compromise the organic polymer layer or the electronic component layer, it is feasible to maintain the protection efficacy of the organic polymer layer, and hence, compared with the conventional package structure, the present invention omits the fabrication of at least one passivation layer having an inorganic material, and at the same time simplifies the fabrication process and the layers of the package structure, thereby reducing the cost and increasing the productivity, and may even reduce the thickness of the package structure.

The foregoing outlines features of preferred embodiments of the present invention; however, the present invention is not limited thereto. As could be appreciated by persons having ordinary skill in the art, there are various changes and modifications to the present invention. Any modifications, equivalent substitutions, improvements and the like are encompassed in the scope of the present invention.

What is claimed is:

1. A package structure, comprising:
a substrate;
an electronic component layer, disposed on the substrate;
an organic polymer layer, disposed on the electronic component layer; and
a protective layer, disposed on the organic polymer layer.

2. The package structure of claim 1, wherein the package structure further comprises an active area, and the electronic component of the electronic component layer is disposed in the active area, wherein in the top view direction of the substrate, the size of the organic polymer layer is greater than the size of the active area.

3. The package structure of claim 1, wherein in the top view direction of the substrate, the size of the substrate is greater than the size of the protective layer, the size of the protective layer is greater than the size of the organic polymer layer.

4. The package structure of claim 1, further comprising at least one inorganic insulating layer disposed between the organic polymer layer and the protective layer or disposed between the organic polymer layer and the electronic component layer.

5. The package structure of claim 4, wherein the inorganic insulating layer comprises a material selected from at least one of silicon oxide, silicon oxynitride and silicon nitride.

6. The package structure of claim 4, wherein the electronic component comprises a plurality of said inorganic insulating layers, wherein the plurality of inorganic insulating layer comprises at least one first inorganic insulating layer and at least one second inorganic insulating layer, the first inorganic insulating layer comprises a material or a ratio between materials that is different from that of the second inorganic insulating layer, and the first inorganic insulating layer and the second inorganic insulating layer are stacked alternately.

7. The package structure of claim 4, wherein in the top view direction of the substrate, the size of the inorganic insulating layer is greater than the size of the organic polymer layer and is smaller than the size of the protective layer.

8. The package structure of claim 1, further comprising an adhesive layer disposed between the organic polymer layer and the protective layer.

9. The package structure of claim 1, further comprising at least one layer of an optical film, disposed on the protective layer.

10. The package structure of claim 1, wherein the organic polymer layer comprises a polymer of at least two compounds polymerizable to form a methyl methacrylate-based polymer.

11. The package structure of claim 10, wherein the organic polymer layer comprises acrylate or derivatives thereof, methyl acrylate or derivatives thereof or methyl methacrylate or derivatives thereof.

12. The package structure of claim 1, wherein the organic polymer layer comprises a polymer having 5%-55% of fluorine.

13. The package structure of claim 1, wherein the organic polymer layer comprises a material capable of isolating moisture and oxygen.

14. The package structure of claim 1, wherein the thickness of the organic polymer layer ranges from 0.1 micrometer to 10 micrometers.

15. The package structure of claim 1, wherein the organic polymer layer is formed by polymerizing oligomers with energy irradiation.

16. The package structure of claim 1, wherein the electronic component layer comprises an organic light-emitting diode structure.

17. The package structure of claim 1, wherein the organic polymer layer is directly disposed on the electronic component layer.
